(19) United States
(12) Patent Application Publication
(10) Pub. No.: US 2014/0327997 A1
(43) Pub. Date: Nov. 6, 2014

(54) Device for Controlling a Power Switch and Related Electrical Appliance

(71) Applicant: Orange, Paris (FR)

(72) Inventor: Pascal Pagani, Brest (FR)

(21) Appl. No.: 14/348,784

(22) PCT Filed: Sep. 25, 2012
(86) PCT No.: PCT/FR2012/052140

§ 371 Date: Jul. 21, 2014

(30) Foreign Application Priority Data
Sep. 30, 2011 (FR) 11 58821

(51) Int. Cl. H01H 47/22; H03H 7/01

(52) U.S. Cl. CPC H01H 47/223; H03H 7/0138; H01H 2231/012; H01H 2300/04
USPC 361/211

(57) ABSTRACT

A device is provided for controlling at least one electrical power supply switch. The device includes at least one input port configured to receive a control signal of the at least one switch and a control circuit coupled to the input port. The control circuit is configured to actuate the at least one switch. The control circuit is electrically passive in the absence of any control signal and is configured to be supplied electrically by the control signal.

### 1. CROSS-REFERENCE TO RELATED APPLICATIONS

This Application is a Section 371 National Stage Application of International Application No. PCT/FR2012/052140, filed Sep. 25, 2012, which is incorporated by reference in its entirety and published as WO 2013/045811 on Apr. 4, 2013, not in English.

### 2. FIELD OF THE INVENTION

The field of the invention is that of the energy supply of electrical apparatuses, such as domestic appliances (televisions, washing machine, etc.) or communication appliances (Power Line Communications (PLC) modem, WiFi access point, etc). More precisely, the invention relates to the remote control of the connection/disconnection of such apparatuses to an electrical power supply network.

### 3. PRIOR ART AND ITS DRAWBACKS

The energy consumption of electrical appliances, whether electrodomestic appliances or communication appliances, constitutes a growing concern of their users. Indeed, consumers are ever more sensitive to the growing cost of energy, on the one hand, and to the environmental impact of energy production, on the other hand.

The manufacturers of these domestic appliances therefore all take the energy efficiency parameter into account in the design of their apparatuses.

Thus, to reduce their energy consumption, most of these domestic apparatuses now exhibit a standby mode, in which they no longer carry out their principal function but exhibit reduced electrical consumption.

In such a standby mode, the apparatus must be able to pass very rapidly to active mode, through a command or a simple action of the user. Thus, for example, a television in standby mode keeps its infrared receiver active, so as to be able to toggle very rapidly to active mode, when the user seeks to turn it back on by simply pressing the associated remote control.

Therefore, even when they are in standby mode, the electrical consumption of these appliances is not zero, thus constituting a drawback of this prior art.

This residual electrical consumption of the appliances in standby mode is also due to the fact that most of these appliances are linked to the mains electrical power supply by way of a transformer (generally from alternating current to direct current), which consumes electrical energy, even when the appliances are in standby mode.

The problem area of the rapid toggling of an electrical appliance from the standby mode to the active mode turns out to be still more complex for the data transmission appliances integrated into systems of WiFi or PLC type for example. Indeed, for such appliances, toggling from the standby mode to the active mode, or vice versa, must be able to be controlled remotely, by a control appliance of the communication system considered.

Thus, a PLC modem for example generally toggles to standby mode on completion of an inactivity period of predefined duration; it must however be able to exit this standby mode rapidly in response to a summons of the communication network's coordinator PLC modem. To address this problem area, the standby mode of the PLC modem is generally based on a significant reduction in the life cycle (or “duty cycle”): instead of communicating in continuous time, the PLC modem is for example operational for only 1% of the time, so as to be able to receive protocol messages, if any, requesting that it be woken up during this short listening period. Consequently, though the electrical consumption of a PLC modem in standby mode is greatly reduced, it is not zero for all that, thus constituting a drawback of this state of the art.

In order to alleviate this drawback, and to solve the dual problem of reducing the electrical consumption of appliances and of the possibility of reactivating them rapidly, including remotely, systems have been proposed which make it possible simultaneously:
to totally cut off the electrical power supply of an appliance, upstream of its transformer (so as to avoid the above-mentioned continuous consumption of the transformer);
to make it possible to activate, remotely, the connection or the disconnection of the appliance to its electrical power supply.

These systems consist of switches that can be controlled remotely by a signal of infrared, radio or GSM type (GSM standing for “Global System for Mobile Communications”) for example, which interface between the appliance whose electrical consumption it is desired to control and its electrical power supply.

Thus, by way of example there may be cited the product “GSM Mini” (trademark) marketed by the company EcoStarter (trademark), which consists of a 230V socket remotely controlled by SMS. This device comprises a male electrical plug, which can be connected to the electrical power supply network, and a female electrical socket into which the appliance whose electrical consumption it is desired to reduce can be plugged, so that this device interfaces between the mains electrical power supply socket and the appliance to be controlled. It moreover comprises an SIM (“Subscriber Identity Module”) card, able to receive a control signal of SMS (“Short Message Service”) type, so as to actuate the opening or the closing of the electrical power supply circuit of the appliance which is connected to it.

Other similar switch systems exist, in which the control signal is not of SMS type, but is for example of infrared or radio type: the operating principle is however similar, namely that the control signal received makes it possible to open or close the electrical power supply circuit of the device whose energy consumption it is sought to curb.

Though these systems of the prior art exhibit the advantage of totally cutting off the electrical power supply of the domestic or communication appliance whose consumption it is sought to reduce, they all exhibit the major drawback, however, of exhibiting non-zero residual electrical consumption. Indeed, all these remotely controllable switch systems must be able to respond immediately on receipt of a control signal (GSM, radio or infrared for example), by opening or closing the electrical power supply circuit of the domestic or communication appliance that they control: accordingly, they therefore comprise means for processing this control signal, which are in standby mode most of the time, but hence therefore exhibit non-zero electrical consumption.

Furthermore, another drawback of these systems of the prior art is that the means for processing the control signal that they comprise are often complex and, hence, expensive.

American patent application US 2009/0271013 thus presents a remotely driven system for controlling the electrical power supply of domestic appliances, by way of switches controlled by way of a control module, which communicates with a remote server by way of a communication module.

In such a system, in addition to the complexity entailed in putting in place the detection and the conversion of the control signals by the communication module, the control module and of the communication module are in a permanent operating state, both to allow the receipt of the control signals originating from the remote server and the dispatching of appliance consumption state signals to this remote server, thus entailing significant electrical consumption.

French patent application FR2488069 presents for its part a signals transmission system in which a unit is actuated remotely. However, the means of actuation of this unit, which comprise notably a demodulator and a decoder, entail non-negligible electrical consumption requiring electrical power supply to these actuation means by way of the mains or of an autonomous battery.

A need therefore exists for a technique for controlling the electrical power supply of an apparatus, controllable remotely, which does not exhibit these various drawbacks of the prior art. Notably, a need exists for such a technique which is simple and inexpensive to implement, and which exhibits zero electrical consumption.

### 4. DESCRIPTION OF THE INVENTION

The invention addresses this need by proposing a device for controlling at least one electrical power supply switch, which comprises at least one input port able to receive a control signal of the switch or switches and control means able to actuate the switch or switches, which are electrically passive in the absence of the control signal and configured to be supplied electrically by means of the control signal.

Thus, the invention relies on an entirely novel and inventive approach to remotely controllable switch devices. Indeed, the invention proposes a device for controlling an electrical power supply switch which is totally passive, so that it exhibits zero electrical consumption, this being particularly advantageous relative to the systems of the prior art which all exhibit non-zero residual electrical consumption.

Indeed, the invention proposes a novel and inventive approach to remotely controllable switches, according to which the energy necessary for the receipt of the control signal and for the opening or the closing of the switch is not provided locally in the switch control device, but is transmitted by a remote entity, by way of the control signal itself.

Furthermore, such a device being totally passive, it is of very simple design, and very inexpensive to manufacture, this not being the case for the devices known in the prior art.

By virtue of a remotely controllable passive switch control device such as this, the invention thus makes it possible to reduce to zero the energy consumption of a domestic or communication appliance when it is not operating, while allowing its rapid reactivation if necessary.

In a preferential embodiment of the invention, such control means comprise at least one relay able to actuate said at least one switch; such a control device moreover comprises at least one passive bandpass filter, able to operate a frequency filtering of the control signal, and which is connected to said at least one relay.

The relay or relays can be of static or electromechanical type.

Such an embodiment is of simple and inexpensive design. The bandpass filter/relay assembly moreover presents the advantage of being totally passive. The relay actuates the opening or the closing of the switch when the voltage across its terminals is sufficient, this voltage being extracted from the control signal by way of the bandpass filter, as set forth in greater detail in conjunction with the figures.

Advantageously, such a control device comprises at least two bandpass filters whose passbands are centered on distinct frequencies.

The reliability of operation of the device of the invention is thereby enhanced, by preventing noise, received on the input port of the device, and contained in the frequency band of the passive bandpass filter, from being wrongly interpreted as a control signal intended to actuate the switch. Indeed, to actuate the switch, it is now appropriate to receive, on the input port of the device, a first signal contained in the frequency band of the first bandpass filter, and a second signal contained in the frequency band of the second bandpass filter. Only the simultaneous receipt of these two signals makes it possible to activate the relay, and thus to actuate the opening or the closing of the switch.

More generally, it may be envisaged that the device comprises N filters, where N is an integer greater than or equal to 2.

According to an advantageous characteristic, such a control device comprises at least two relays, a first relay able to actuate the opening of the switch and a second relay able to actuate the closing of the switch.

Indeed, the device of the invention can be designed on the basis of a simple relay, i.e. a relay which, actuated a first time, causes the opening of the switch, and then which, actuated a second time, causes the closing of the switch (or vice versa). It can also be designed on the basis of a double relay, or of two relays, thereby making it possible advantageously to discriminate the opening and the closing of the switch, and therefore making it possible to refine its control.

According to an advantageous variant embodiment, such a control device comprises at least two relays, a first relay able to actuate a first switch and a second relay able to actuate a second switch.

In this variant embodiment, the switches are preferably mounted in series, and each relay is associated with a bandpass filter, so that the electrical power supply circuit of the appliance whose energy consumption it is sought to control is closed if, and only if, the signal received on the input port includes frequency components in each of the frequency bands of the various bandpass filters of the device.

It is also possible to envisage that a relay is controlled by two (or more) bandpass filters. In this case, the two (or more) filters are in parallel, and the relay is actuated if the voltage across its terminals originating from the sums of the two (or more) filters is sufficient.

Preferably, such a control device also comprises a control port connected to said at least one relay.

Thus, the switch can be, either controlled remotely by a control signal received on the input port, or controlled directly by a local entity, able to inject the appropriate voltage across the terminals of the relay, by way of the control port. The latter variant turns out to be particularly advantageous in the case where the appliance whose energy consumption it is sought to curb is for example an appliance of a communication network. In this case, the toggling of this appliance to disconnected mode may result from a negotiation between two communicating entities, using a communication protocol specific to the communication system considered. On completion of the negotiation, the disconnection of the appliance can be performed, either by the remote entity which emits a control signal received on the input port of the device of the invention, or by the local entity, by way of the control port of this device.

In a first advantageous embodiment, the input port is a male electrical contact, the control device comprises a female electrical contact connected to the male electrical contact by at least one phase wire and at least one neutral wire, and the switch is situated on one of the phase wires linking the male electrical contact and the female electrical contact.

Thus, the appliance whose energy consumption it is sought to control is plugged into the device of the invention, which is itself plugged into the electrical power supply network. In this case, the control signal is of PLC type. Indeed, the electrical network is particularly adapted for transmitting such a control signal, since it allows the receipt of a signal with sufficient power to actuate a relay in a passive manner.

In a second advantageous embodiment, the input port is of optical type, and the bandpass filter is a passive optical bandpass filter.

This type of device is particularly adapted for controlling the electrical power supply of the appliances present on an optical communication network.

In a third advantageous embodiment, the control signal is a radio signal and the device comprises an antenna able to receive the radio signal and to transmit it to the input port.

According to an advantageous variant, this device furthermore comprises an energy storage element inserted between the input port and the control means, thereby allowing the power supply of the control means and the toggling of the switch by means of control signals with low energy level, such as optical or radio control signals.

The invention also relates to an electrical apparatus comprising a device for controlling an electrical power supply switch such as described previously.

Indeed, the device of the invention can take the form of an independent module, able to be connected to the electrical apparatus whose electrical consumption it is desired to control, or be integrated directly into this apparatus.

Advantageously, such an apparatus is a Power Line Communications modem.

### 5. LIST OF FIGURES

Other advantages and characteristics of the invention will be more clearly apparent on reading the following description of a particular embodiment of the invention, given by way of simple illustrative and nonlimiting example, and the appended drawings, among which:

FIG. 1 presents a first exemplary control device of the invention, in the form of a housing comprising a male electrical contact and a female electrical contact;

FIG. 2 illustrates a variant embodiment of the device of FIG. 1, in which this device exhibits a control port;

FIGS. 3A and 3B present a second exemplary control device of the invention, which differs from that of FIG. 1 in that it comprises an antenna able to receive a control signal of radio type;

FIG. 4 describes a device in accordance with the invention which comprises a plurality of bandpass filters and of relays;

FIG. 5 presents a domestic network to which are connected several appliances in each of which is integrated a device in accordance with FIG. 1.

### 6. DESCRIPTION OF A PARTICULAR EMBODIMENT OF THE INVENTION

The general principle of the invention relies on the design of a totally passive device, which can be controlled remotely, to control the opening or the closing of a switch of the electrical power supply circuit of an appliance.

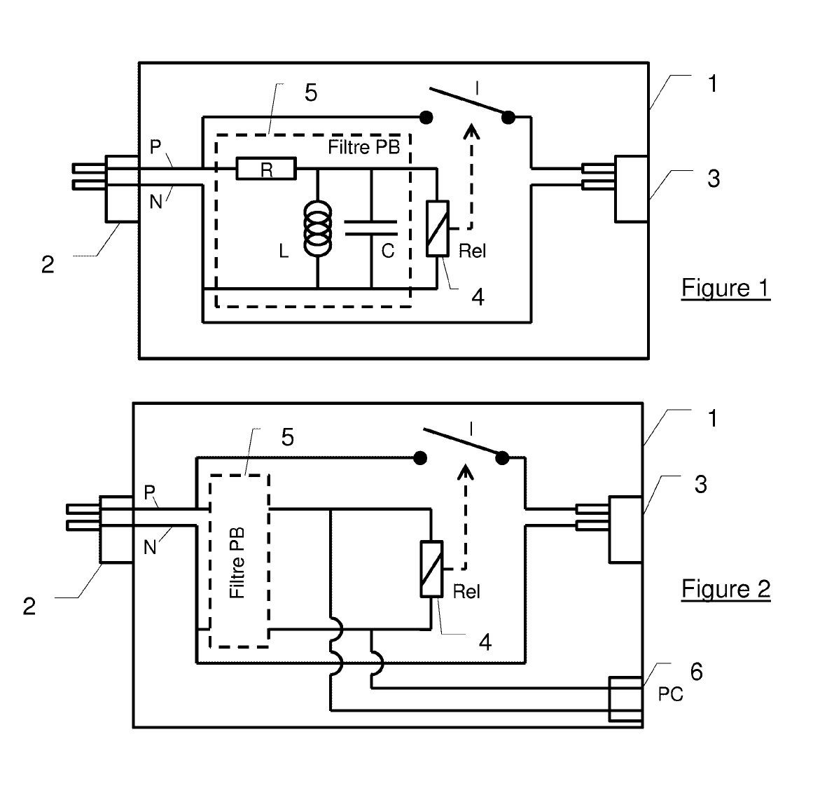

The device 1 takes the form of a housing, comprising a male electrical contact 2 and a female electrical contact 3, as well as control means 4, 5 for a switch I, which comprise a relay Rel 4 and a bandpass filter 5 in the example illustrated in FIG. 1.

The male current contact 2 is connected to the female current contact 3 by way of phase P and neutral N wires. For the sake of simplification, the possible direct connection of the earth wire between the male contact 2 and female contact 3 is not represented in FIG. 1. The phase wire P is furnished with a switch I controlled with the aid of the abovementioned control means.

The male electrical plug 2 is intended to be connected to a female electrical contact of an electrical power supply network (for example a domestic electrical network), and the female electrical socket 3 is intended to receive a male electrical plug of an appliance whose idle-operation electrical consumption it is sought to reduce (for example a television or a PLC modem).

The control means 4, 5 of the switch I are electrically passive in the absence of any control signal, i.e. they do not need to consume electrical energy to remain in a quiescent state in which they are inactive and do not act on the switch I.

The electrical consumption of these control means can thus be considered to be substantially zero in the absence of any control signal, disregarding possible unintentional leakage currents which induce negligible electrical consumption.

These control means are configured to be supplied electrically by means of a control signal, which then intrinsically provides the energy necessary for these control means to open or close the switch I, without these control means needing to be supplied electrically by means other than this control signal. Stated otherwise, these control means can operate without being supplied electrically by the electrical network.

Thus, to return to the embodiment illustrated in FIG. 1, when a voltage V is present across the terminals of the relay Rel 4, the latter actuates the switch I, to open it or close it. Indeed, in FIG. 1, the relay Rel 4 represented is a simple relay, i.e. that successive actions of the relay lead to the opening, and then to the closing of the switch.

In a variant embodiment of the device 1, the relay Rel 4 could be replaced with a dual relay, or with any other passive device making it possible to discriminate the opening and the closing of the switch I.

The relay Rel 4 is supplied by the phase P and neutral N wires by way of a bandpass filter 5. Such a filter 5 is preferably frequency selective, and filters any signal situated outside of a frequency band centered on a frequency FO. This filter 5 being passive, the device 1 does not exhibit any electrical consumption during nominal operation, i.e. when no electrical signal is present in the frequency band centered on FO at the terminals of the filter 5.

In the example of FIG. 1, the bandpass filter 5 comprises a resistor R, an inductance L and a capacitor C. The invention relates of course also to a device such as represented in FIG. 1, in which the bandpass filter 5 were replaced with any other passive filter device producing the same effect.

In disconnected mode, the switch I is open, and the apparatus connected on the female contact 3 side is not supplied. When a signal, exhibiting a frequency component included in the frequency band of the bandpass filter 5, is received on the input port consisting of the male electrical contact 2, it constitutes a control signal: at the output of the bandpass filter 5, the voltage across the terminals of the relay Rel 4 passes to a value V, and the relay Rel 4 therefore actuates the closing of the switch I.

Such a control signal is for example transmitted on the electrical network by a remote appliance, so as to reactivate the operation of the apparatus connected on the female contact 3 side. A remote appliance such as this is for example a control module able to emit the appropriate control signal for closing the switch I remotely.

On receipt of this control signal, the apparatus plugged into the device 1 exits a disconnected mode, and turns on as if it had just been plugged into the mains.

The invention finds notably application in the case where the device 1 is directly integrated into a PLC modem, and where a communication network comprising a plurality of PLC modems each furnished with an integrated disconnection switch 1 is considered. In this case, control signals of distinct frequencies are used to drive each device 1 for disconnection of each of the modems of the network. In this manner, a coordinator modem for the network can decide to disconnect each of the modems of the network, on completion of a predetermined inactivity time for example. It keeps a table of the modems that it can reach, but in disconnected mode. In this manner, when a transmission is intended for a modem of the network which is in disconnected mode, the coordinator module emits the appropriate control signal, so as to reset the recipient modem to connected mode.

In the embodiment described hereinabove in conjunction with FIG. 1, the command for opening or closing the switch I is transmitted remotely by a control module which has not been illustrated, for the sake of simplification.

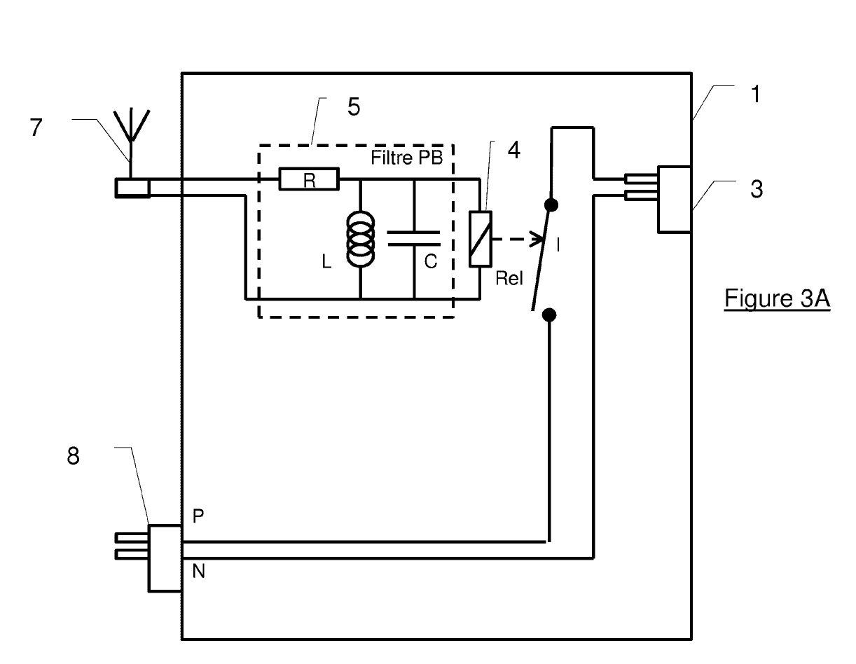

This command can also be transmitted by a local appliance, connected to the device 1, as illustrated in FIG. 2. In this variant embodiment, the device 1 comprises a control port PC referenced 6, on which a local appliance, which has not been represented for the sake of simplification, can directly inject the appropriate voltage V across the terminals of the relay Rel 4.

Indeed, the toggling of the appliance whose energy consumption it is sought to curb to disconnected mode can result from a negotiation between two communicating entities of a communication network, namely a local entity and a remote entity. This variant finds notably application in the case where the appliance whose energy consumption it is sought to curb is a communication modem, for example of PLC type: the remote entity is then the network coordinator modem, and the local entity is another appliance of the domestic network, such as the residential gateway for example.

By way of example, such a variant is particularly advantageous in the case of a communication network (for example within a domestic framework) comprising a communication gateway connected by Ethernet cable to a first PLC modem, capable of communicating with a second PLC modem connected to a PC by Ethernet cable. In the absence of traffic on the network, the two PLC modems place themselves on standby. The residential gateway remains awake to receive data originating from the access network. When it must dispatch data to the PC, it awakens the first PLC modem via the control port of the control device which is connected to it or integrated therewith, and then the first PLC modem (or the gateway) awakens the second PLC modem via the electrical line: the transmission of data between these various appliances can then commence.

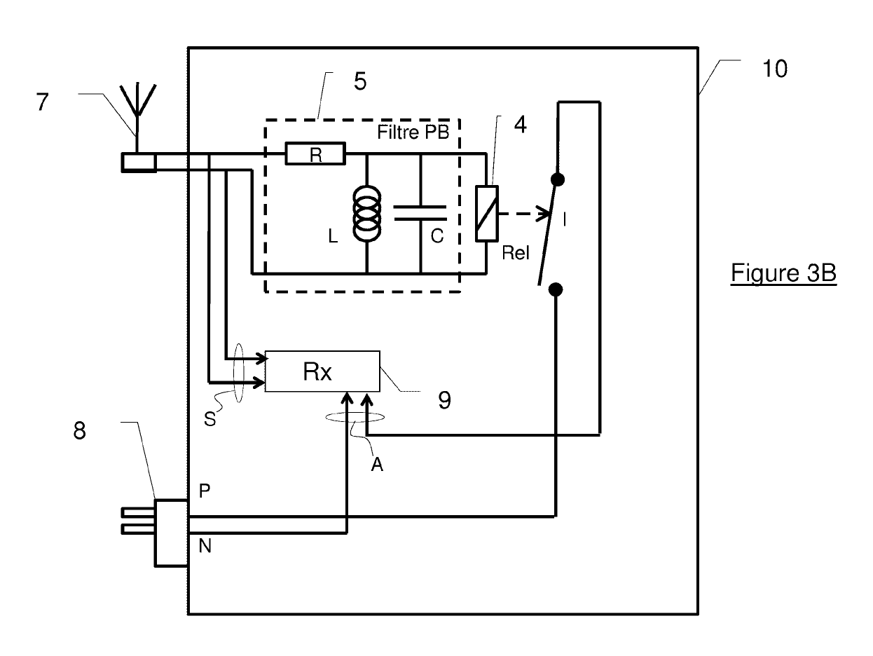

A variant embodiment of the device of FIG. 1, in which the control signal is transmitted to the device in the form of an electromagnetic signal, received on an antenna 7, is now described in conjunction with FIGS. 3A and 3B.

In the example of FIG. 3A, the passive antenna 7 constitutes the input port of the device 1, on which the control signal is received. A bandpass filter BP 5 filters the components of the control signal received on the antenna, so as to allow through only the frequency components included in a passband centered on a frequency FO. If such frequency components are included in the signal received on the antenna 7, a voltage V across the terminals of the relay Rel 4 is obtained as output from the filter BP 5, so that the relay actuates the switch I. If the device 1 is linked to the mains by way of the male electrical plug 8, and to the appliance whose energy consumption it is sought to control by way of the female electrical socket 3, the opening of the switch I makes it possible to interrupt the electrical power supply to this appliance, and thus to toggle the latter to disconnected mode.

In the example illustrated by FIG. 3B, the control device of the invention is integrated into a radio communication system 10, whose idle-operation energy consumption it is sought to reduce. Such a system 10 comprises a radio receiver Rx 9, intended to receive or emit a communication signal. The antenna 7, constituting the input port of the control device of the invention, is linked to this radio receiver Rx 9, to which it provides the control signal S.

The radio receiver Rx 9 is linked to the electrical power supply network by virtue of the male electrical contact 8. In accordance with the invention, its energy supply (A) is controllable, as a function of the open or closed state of the switch I.

In FIG. 3, the bandpass filter is a passive filter of RLC type, comprising a resistor R, an inductance L and a capacitor C. Just as for the devices of FIGS. 1 and 2, the device of FIG. 3 can also be modified to integrate any other type of passive bandpass filter.

By way of variant, it is also possible to envisage that the device 1 of FIG. 3 does not comprise any male electrical plug 8, but that the switch I is situated on an internal electrical power supply circuit linking the appliance whose energy consumption it is sought to reduce to a battery.

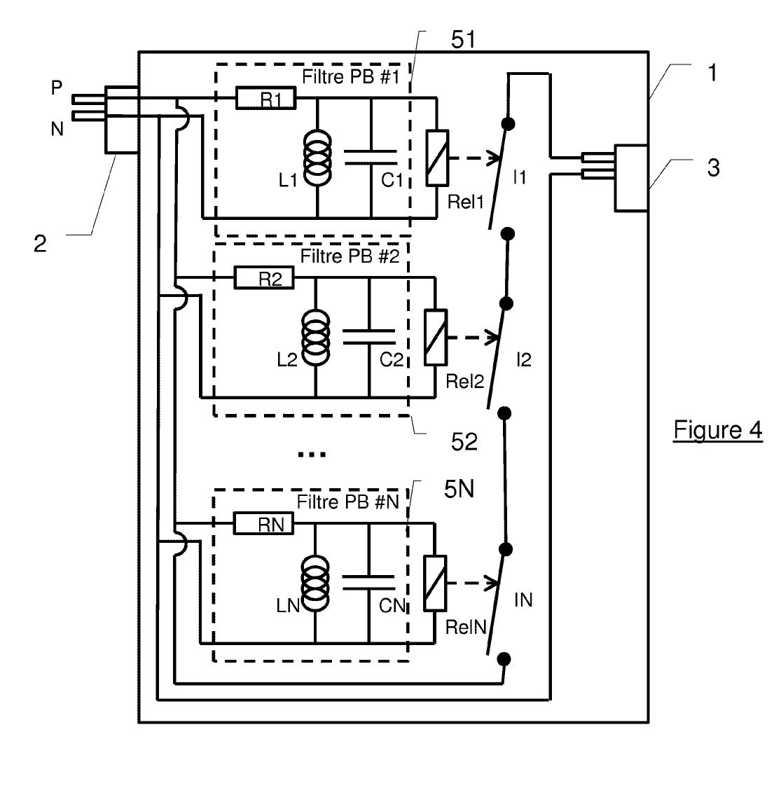

FIGS. 1 and 3 illustrate two embodiments of the invention, one in which the control signal is transmitted by an electrical network, and the other in which the control signal is transmitted in the form of electromagnetic waves. It would also be possible to envisage an embodiment, not illustrated, in which the control signal were transmitted in optical form. In this case, the device 1 in accordance with the invention would exhibit an input port able to receive a control signal transmitted by optical fiber: the device 1 would then comprise an optical bandpass filter able to filter the optical signal received, disposed upstream of a relay, in accordance with FIGS. 1 and 4.

A variant embodiment of the device 1 of FIG. 1, in which the device 1 comprises a plurality of bandpass filters and of relays, is now presented in conjunction with FIG. 4.

As in FIG. 1, the device 1 comprises a male electrical contact 2 forming the input port of the device, able to receive a control signal originating from a remote control module.

The male current contact 2 is connected to a female current contact 3 by way of phase P and neutral N wires. For the sake of simplification, the earth wire that may link the male contact 2 and female contact 3 has not been represented.

The male electrical contact 2 can be plugged into a domestic electrical power supply network for example; the female electrical contact 3 can for its part receive an electrical appliance whose toggling from a connected mode to a disconnected mode, and vice versa, it is desired, according to the invention, to be able to control remotely.

The phase wire P is furnished with a plurality of switches referenced I1, I2 to IN, mounted in series. Each of these switches I1 to IN is controlled with the aid of a relay referenced Rel1 to ReIN. Each of these relays Rel1 to ReIN is disposed at the output of a passive bandpass filter 51 to 5N (Filter BP #1 to Filter BP #N). In FIG. 4, each of the these passive bandpass filters exhibits a simple architecture of RLC type, comprising a resistor R1 to RN, an inductance L1 to LN, and a capacitor C1 to CN.

In a preferential manner, each of these filters 51 to 5N exhibits a passband centered on a distinct central frequency, so that a distinct frequency component serves to drive each of the relays Rel1 to ReIN. Stated otherwise, the electrical appliance connected to the female electrical contact 3 is supplied only when the control signal received on the input port consisting of the male electrical contact 2 includes the N frequency components included in the N passbands of the N filters 51 to 5N.

In FIG. 4, all the switches I1 to IN are in the open state in the initial state, and toggle to the closed state, subsequent to the receipt of an appropriate control signal on the male electrical contact. By way of variant, certain switches may be in the closed state in the initial state, while others are in the open state. Thus, in an exemplary device 1 comprising three switches I1, I2 and I3, it may be imagined that the switches I1 and I2 are initially in an open state, and that the switch I3 is initially in a closed state. The electrical power supply circuit linking the male electrical contact 2 and female electrical contact 3 therefore toggles to the closed state only if the control signal received on the male electrical contact 2 includes frequency components at the frequencies F1 and F2 (namely the central frequencies of the passbands of the bandpass filters 51 and 52) but does not include any frequency component at the frequency F3 (namely the central frequency of the passband of the bandpass filter 53).

In another variant embodiment of the device 1 of FIG. 4, one (or several) of the relays Rel1 to ReIN is not controlled by one but by two (or more) bandpass filters. In this case, the two (or more) bandpass filters are mounted in parallel, and the relay that they control actuates the associated switch when the voltage across its terminals, originating from the sum of the two (or more) filters, is sufficient.

Presented in conjunction with FIGS. 1 to 4 is a first embodiment in which the control device of the switch in accordance with the invention is designed on the basis of a bandpass filter and of a relay, energized by the control signal of the switch, received on the input port from a remote entity.

It will be noted that other embodiments are conceivable. Thus, the means for actuating the switch can take the form of an electronic control, supplied on the basis of an energy storage element, such as a cell, an accumulator or a battery. The electronic control actuates the opening or the closing of the switch only when the energy storage element exhibits a charge level greater than a predetermined threshold. Moreover, the charging of the energy storage element starts when the voltage across its terminals is sufficient. This voltage is provided by a remote appliance, in the form of the control signal received on the input port of the device.

This embodiment is particularly advantageous when the control signal exhibits relatively low energy levels, as may be the case for an optical or radio control signal. It may thus be advantageous to insert such an energy storage element between the input port which receives the control signal and the control means of the switch I, so as to allow the toggling of the switch I even in cases where the energy transmitted by the control signal were not sufficient to cause such toggling.

In such an embodiment, the electrical energy afforded by such control signals with low energy accumulates at the level of this energy storage element until the voltage across the terminals of this energy storage element becomes greater than the voltage value for which the control means opens or closes the switch I (typically the voltage value necessary for the toggling of the relay 4 in the example of FIG. 1).

In order to discriminate the control signal from the other signals received on the input port of the device of the invention, two variant embodiments are proposed:
in a first variant, frequency discrimination of the control signal is operated, by means of a bandpass filter such as described previously in conjunction with FIGS. 1 to 4 for example;
in a second variant, voltage discrimination of the control signal is operated. Stated otherwise, the charging of the storage element starts only when the voltage across its terminals is greater than a predetermined threshold, this threshold being higher than the voltage of the other signals present on the control signal transmission medium and received on the input port.

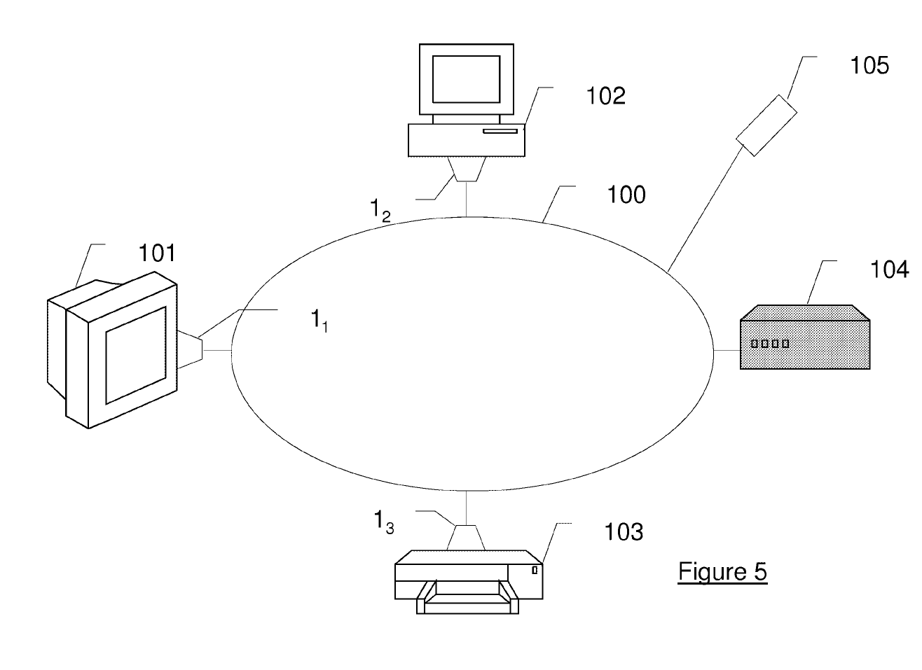

An exemplary domestic electrical network 100, to which a television 101, a computer 102 and a printer 103 are connected, is now presented in conjunction with FIG. 5. A communication gateway 104 of Livebox (trademark) type for example is also plugged into this electrical power supply network 100. Each of these domestic appliances referenced 101 to 103 is connected to the electrical power supply network 100 by way of a control device in accordance with the invention, referenced respectively 1₁ to 1₃.

A central control module 105 allows the user of these domestic appliances to set them all to idle when they are unused for a long period, at night for example. This central control module 105 dispatches a control signal by way of the electrical network 100: this control signal is received on each of the control devices 1, to 1₃, where it is filtered and makes it possible to actuate an associated switch. In disconnected mode, these apparatuses together have zero electrical consumption, in contradistinction to the standby modes known in the prior art.

At the opportune moment, in the morning for example, the central control module 105 can power up all the apparatuses, in a programmed manner (at fixed times for example), or by intervention of the user.

The user can also use the central remote control 105 to set just one of the apparatuses of his network to idle, such as the television 101 for example, by emitting a control signal which is specific to the control device 1₁.

By way of variant, the central control module can be integrated into the communication modem 104: in this case, it is this communication gateway 104 which dispatches the control signals to connect or disconnect each of the electrical apparatuses 101 to 103 of the network.

Of course, the invention is not limited to the exemplary embodiments described and represented hereinabove, on the basis of which it will be possible to envisage other modes and other embodiments, without however departing from the scope of the invention.

1. A device for controlling at least one electrical power supply switch, comprising:
at least one input port configured to receive a control signal of said at least one switch; and
a control circuit coupled to the input port and configured actuate said at least one switch, said control circuit being electrically passive in the absence of any control signal and configured to be supplied electrically by the control signal.

2. The control device as claimed in claim 1, the control circuit comprises at least one relay configure to actuate said at least one switch, and said control device comprises at least one passive bandpass filter configured to operate a frequency filtering of said control signal, said at least one bandpass filter being connected to said at least one relay.

3. The control device as claimed in claim 2, wherein the control device comprises at least two bandpass filters whose passbands are centered on distinct frequencies.

4. The control device as claimed in claim 2, wherein the control device comprises at least two relays, including a first relay that actuates an opening of said switch and a second relay that actuates a closing of said switch.

5. The control device as claimed in claim 2, wherein the control device comprises at least two relays, a first relay that actuates a first switch and a second relay that actuates a second switch.

6. The control device as claimed in claim 2, wherein the control device also comprises a control port connected to said at least one relay.

7. The control device as claimed in claim 1, wherein said input port is a male electrical contact, and said control device comprises a female electrical contact connected to said male electrical contact by at least one phase wire and at least one neutral wire, and said switch is situated on said at least one phase wire linking said male electrical contact and said female electrical contact.

8. The device as claimed in claim 1, wherein said input port is of an optical type, and said bandpass filter is a passive optical bandpass filter.

9. The device as claimed in claim 1, wherein said control signal is a radio signal and said device comprises an antenna configured to receive said radio signal and to transmit it to said input port.

10. The device as claimed in claim 1, furthermore comprising an energy storage element inserted between the input port and the control circuit.

11. An electrical apparatus comprising:
a device for controlling an electrical power supply switch, the device comprising:
at least one input port configured to receive a control signal of said at least one switch; and
a control circuit configured to actuate said at least one switch, said control circuit being electrically passive in the absence of any control signal and configured to be supplied electrically by the control signal.

12. The electrical apparatus as claimed in claim 11, wherein said apparatus is a Power Line Communications modem.
